(19) United States
(12) Patent Application Publication
(10) Pub. No.: US 2020/0194459 A1
(43) Pub. Date: Jun. 18, 2020

(54) SEMICONDUCTOR DEVICES AND METHODS FOR FABRICATING THE SAME

(71) Applicant: Vanguard International Semiconductor Corporation, Hsinchu (TW)

(72) Inventors: Chia-Ming HSU, Taichung City (TW); Hsu-Cheng LIU, Jhubei City (TW); Chia-Lin CHEN, Hsinchu City (TW); Jian-Hsing LEE, Puzih City (TW)

(73) Assignee: Vanguard International Semiconductor Corporation, Hsinchu (TW)

(21) Appl. No.: 16/223,866

(22) Filed: Dec. 18, 2018

(51) Int. Cl. H01L 27/12; H01L 21/28; H01L 21/762; H01L 29/49; H01L 29/786

(52) U.S. Cl. CPC H01L 27/1203; H01L 21/28167; H01L 29/78603; H01L 21/7624; H01L 29/4908; H01L 21/76224

(57) ABSTRACT

A semiconductor device includes a SOI substrate, first and second active elements, and an interconnect structure. The SOI substrate includes a semiconductor layer which includes first and second semiconductor blocks separated from each other by an isolation structure. The first and second active elements are disposed on the first and second semiconductor blocks respectively. A source/drain region of the first active element is electrically connected to a gate structure of the second active element through a first path provided by the interconnect structure. The second semiconductor block is electrically connected to the second semiconductor block through a second path provided by the interconnect structure. The second path includes a contact that is in contact with the upper surface of the second semiconductor block.

### BACKGROUND

### Technical Field

The disclosure relates to semiconductor devices, and more particularly, to a semiconductor device with an SOI substrate and methods for fabricating the same.

### Description of the Related Art

Semiconductor structures are used in a variety of electronic applications, such as personal computers, cell phones, digital cameras, and other electronic devices. These semiconductor structures are typically fabricated by depositing an insulating layer or dielectric layer, a conductive layer material, and a semiconductor layer material on the semiconductor substrate in sequence, followed by patterning the various material layers using a photolithography process. Therefore, the circuit devices and components are formed on the semiconductor substrate.

Semiconductor structures that include a silicon-on-insulator (SOI) substrate have shown promise in the semiconductor industry because they have the potential advantages of fast operation, low power loss, latch-up immunity, a simple manufacturing processes, and small dimensions. Although the existing SOI substrate technology has been generally meet the requirements set on it, it is not satisfactory in all respects.

### SUMMARY

Some embodiments of the present disclosure provide a semiconductor device. The semiconductor device includes a silicon-on-insulator (SOI) substrate. The SOI substrate includes a semiconductor substrate, a semiconductor layer, and a buried oxide layer disposed between the semiconductor substrate and the semiconductor layer. The semiconductor layer includes a first semiconductor block and a second semiconductor block which are separated from each other by an isolation structure in the semiconductor layer. The semiconductor device includes a first active element and a second active element disposed on the first semiconductor block and the second semiconductor block respectively. The semiconductor device includes an interconnect structure disposed over the semiconductor layer. The interconnect structure includes a plurality of contacts and multiple layered metal lines sequentially arranged over the plurality of contacts to provide a first path and a second path. A source/drain region of the first active element is electrically connected to a gate structure of the second active element through the first path. The first semiconductor block is electrically connected to the second semiconductor block through the second path. The second path includes a first contact that is in contact with the upper surface of the second semiconductor block.

Some embodiments of the present disclosure provide a method for fabricating a semiconductor device. The method includes providing a silicon-on-insulator (SOI) substrate. The SOI substrate includes a semiconductor substrate, a semiconductor layer, and a buried oxide layer between the semiconductor substrate and the semiconductor layer. The method includes forming an isolation structure in the semiconductor layer so that the semiconductor layer is divided into a first semiconductor block and a second semiconductor block by the isolation structure. The method includes forming a first active element and a second active element on the first semiconductor block and the second semiconductor block respectively. The method includes forming an interconnect structure over the semiconductor layer. The interconnect structure includes a plurality of contacts and multiple layered metal lines sequentially arranged over the plurality of contacts to provide a first path and a second path. A source/drain region of the first active element is electrically connected to a gate structure of the second active element through the first path. The first semiconductor block is electrically connected to the second semiconductor block through the second path. The second path includes a first contact that is in contact with the upper surface of the second semiconductor block.

In order to make features and advantages of the present disclosure easy to understand, a detailed description is given in the following embodiments with reference to the accompanying drawings.

### BRIEF DESCRIPTION OF THE DRAWINGS

The embodiments of the disclosure can be more fully understood by reading the subsequent detailed description and examples with references made to the accompanying drawings. For clarity of illustration, various elements in the drawings may not be drawn to scale, wherein:

FIGS. 1A-1C are cross-sectional views of semiconductor devices in accordance with some embodiments of the present disclosure;

FIGS. 2A-2C are cross-sectional views of semiconductor devices in accordance with some other embodiments of the present disclosure;

FIG. 3A is a top view of a semiconductor device in accordance with some embodiments of the present disclosure; and

FIG. 3B is a top view of a semiconductor device in accordance with some embodiments of the present disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first component over or on a second component in the description that follows may include embodiments in which the first and second components are formed in direct contact, and may also include embodiments in which additional components may be formed between the first and second components, such that the first and second components may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of some embodiments are discussed below. Throughout the various views and illustrative embodiments, like reference numbers are used to designate like elements. It should be understood that additional operations can be provided before, during, and after the method, and some of the operations described can be replaced or eliminated for other embodiments of the method.

The embodiments of the present disclosure is related to a semiconductor device, and more particularly, to a semiconductor device with an SOI substrate and a method for fabricating the same. In the embodiments of the present disclosure, the induced charges formed in the different semiconductor blocks due to plasma-based processes can be balanced through a discharge path provided by the interconnect structure, thereby reducing the likelihood of plasma induced damage (PID).

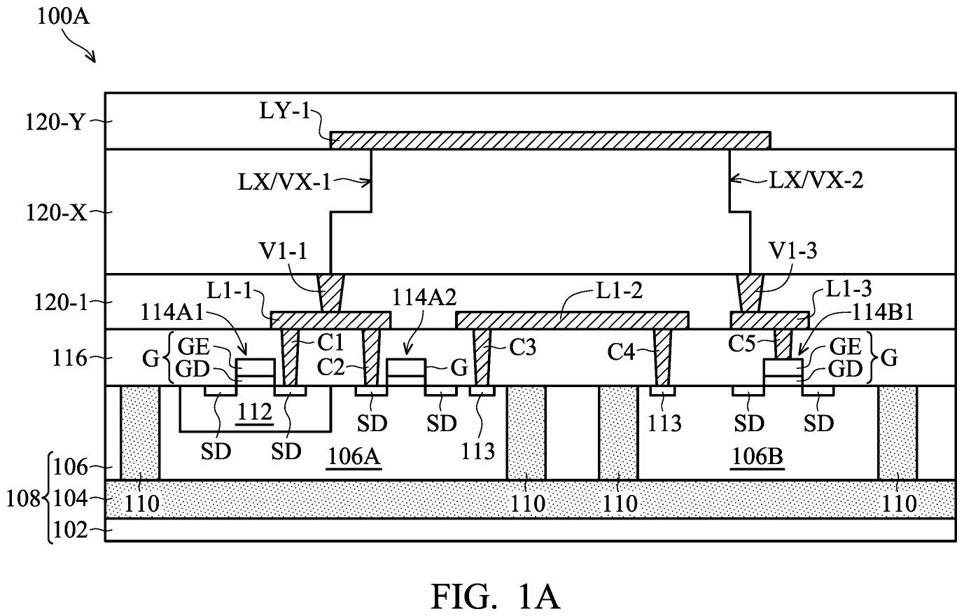

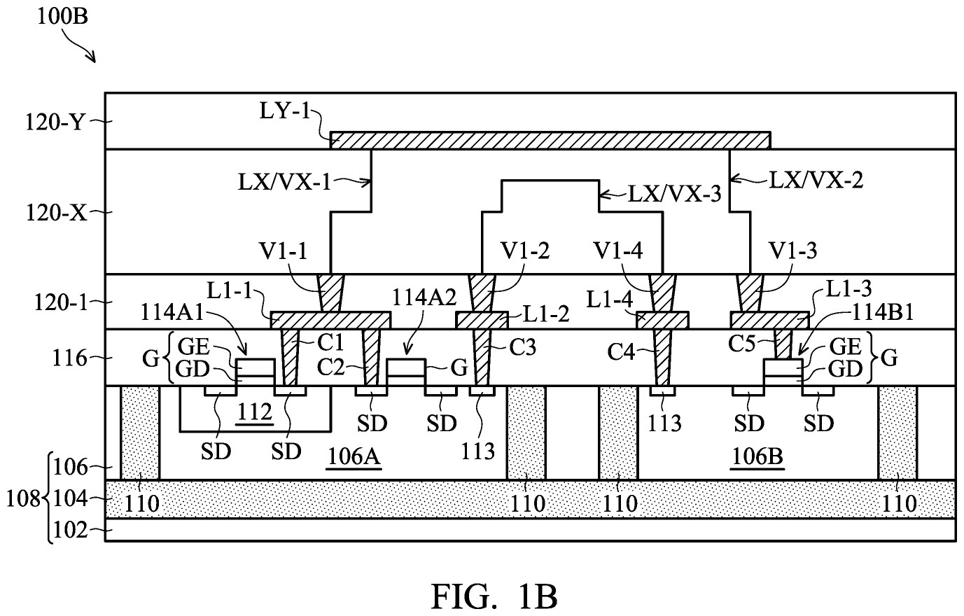

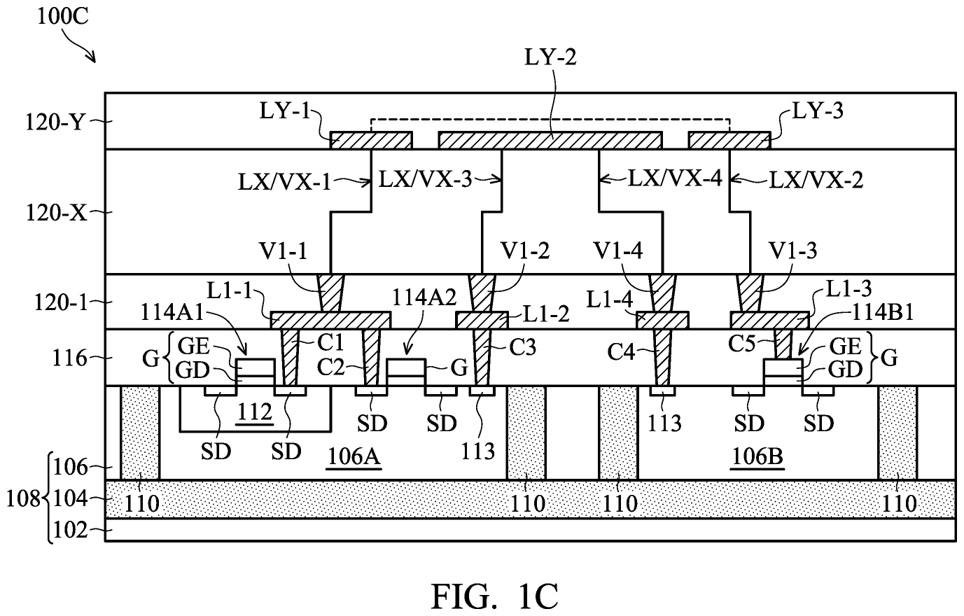

Refer to FIG. 1A, which is a cross-sectional view of a semiconductor device 100A in accordance with some embodiments of the present disclosure. First, a silicon-on-insulator (SOI) substrate 108 is provided. In some embodiments, the SOI substrate 108 includes a semiconductor substrate 102, a buried oxide (BOX) layer 104 formed over the semiconductor substrate 102, and a semiconductor layer 106 formed over the BOX layer 104. In some embodiments, the SOI substrate 108 may be formed by a separation by implantation of oxygen (SIMOX) technology, a wafer bonding process, an epitaxial layer transfer process, or another suitable process.

In some embodiments, the semiconductor substrate 102 may be a silicon (Si) substrate. In some other embodiments, the semiconductor substrate 102 may include an elementary semiconductor such as germanium (Ge); a compound semiconductor such as gallium nitride (GaN), silicon carbide (SiC), gallium arsenide (GaAs), gallium phosphide (GaP), indium phosphide (InP), indium arsenide (InAs), and/or indium antimonide (InSb); and/or an alloy semiconductor such as SiGe, GaAsP, AlInAs, AlGaAs, GaInAs, GaInP, and/or GaInAsP. In some embodiments, the semiconductor substrate 102 may be doped such as with p-type or n-type dopants, or it may be undoped.

In some embodiments, the BOX layer 104 may be made of, or include, silicon oxide. In some embodiments, the BOX layer 104 may have a thickness in a range from about 0.3 μm to about 5 μm. In some embodiments, the semiconductor layer 106 may be made of, or include, silicon (Si) formed by epitaxial growth. In some embodiments, the semiconductor layer 106 may be doped such as with p-type or n-type dopants. For example, during the epitaxial growth process for forming the semiconductor layer 106, the semiconductor layer 106 may be in situ doped. In some embodiments, the conductivity type of the semiconductor layer 106 is p-type. The semiconductor layer 106 may also be referred to as the active layer which is used to form active elements or circuitry devices thereon and/or therein. In some embodiments, the semiconductor layer 106 may have a thickness in a range from about 1 μm to about 15 μm.

Next, an isolation structure 110 is formed in or through the semiconductor layer 106. The semiconductor layer 106 is divided into a first semiconductor block 106A and a second semiconductor block 106B by the isolation structure 110. The isolation structure 110 extends from the upper surface of the semiconductor layer 106 downward to contact the upper surface of the BOX layer 104. The first semiconductor block 106A and the second semiconductor block 106B is each a closed region surrounded by the isolation structure 110, thereby electrically isolating the first semiconductor block 106A from the second semiconductor block 106B. The isolation structure 110 may also be referred to as the deep trench isolation (DTI) structure.

In some embodiments, the isolation structure 110 may be made of, or include, an insulating material, such as an oxide (e.g., silicon oxide), a nitride (e.g., silicon nitride), or a combination thereof. The isolation structure 110 may be formed by performing a patterning process (including photolithography and etching processes) on the semiconductor layer 106 to form trenches passing through the semiconductor layer 106 and exposing the BOX layer 104. One or more insulating materials are then formed over the semiconductor layer 106 and fill the trenches. In some embodiments, the deposition processes for forming the insulating material may be chemical vapor deposition (CVD), such as plasma enhanced CVD (PECVD), or high-density plasma CVD (HDP-CVD); or atomic layer deposition (ALD). Next, a planarization process such as chemical mechanical polishing (CMP) process is performed on the insulating material to remove the insulating material formed above the semiconductor layer 106 so that the upper surface of the isolation structure 110 is level with the upper surface of the semiconductor layer 106.

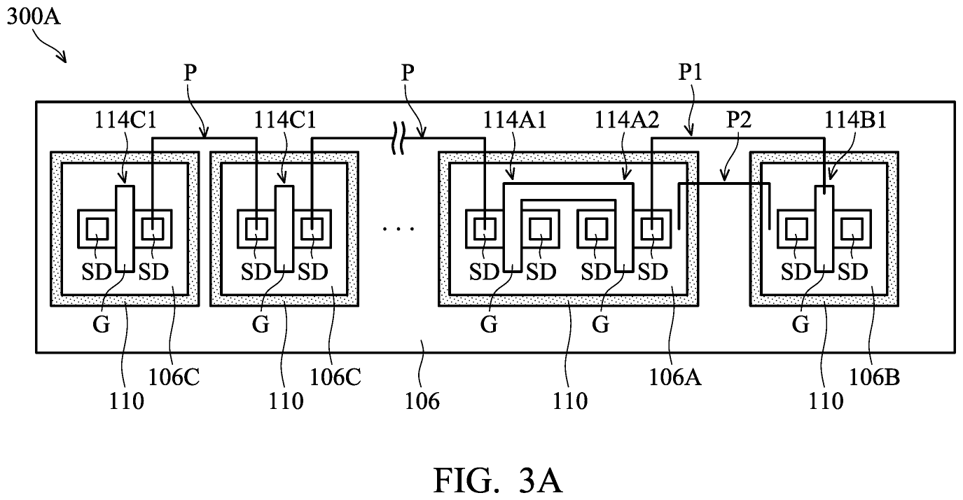

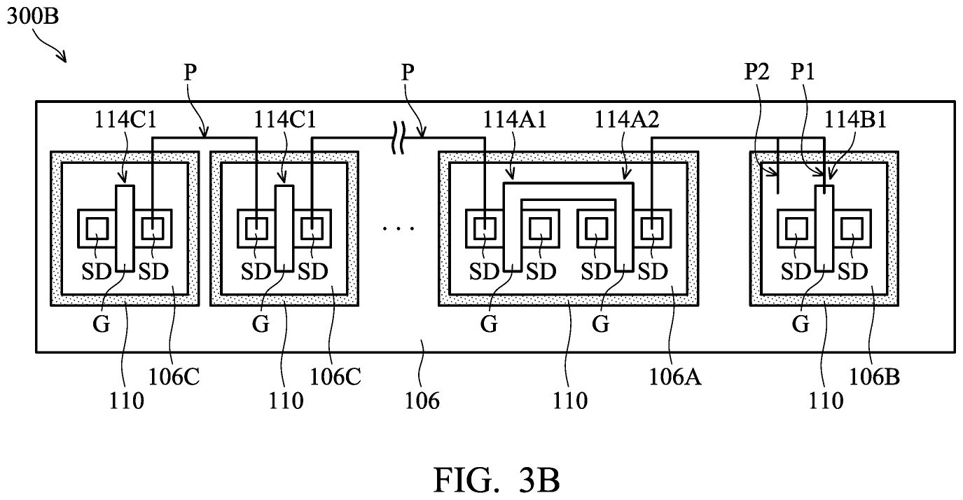

In the embodiments shown in FIG. 1A, the isolation structure 110 defines two separate semiconductor blocks 106A and 106B. In some other embodiments, the isolation structure 110 may define more than two semiconductor blocks separated from each other. For example, FIGS. 3A and 3B show multiple separate semiconductor blocks.

Optionally, one or more well regions or doped regions may be formed in the first semiconductor blocks 106A and the second semiconductor blocks 106B by implantation processes.

In some embodiments, a well region 112 is formed in the first semiconductor block 106A and adjacent to the upper surface of the first semiconductor block 106A. In some embodiments, the conductivity type of the well region 112 is n-type.

In some embodiments, a doped region 113 is formed in the first semiconductor block 106A and adjacent to the upper surface of the first semiconductor block 106A. In some embodiments, another doped region 113 is formed in the second semiconductor block 106B and adjacent to the upper surface of the second semiconductor block 106B. The conductivity type of the doped regions 113 may be n-type or p-type. The doped regions 113 are helpful in reducing the contact resistance (R_{c}) of a contact subsequently formed thereon.

After the well region 112 and the doped regions 113 are optionally formed, one or more active elements are formed on and/or in each of the first and second semiconductor blocks 106A and 106B. For example, active elements 114A1 and 114A2 are formed on the first semiconductor block 106A. For example, an active element 114B1 is formed on the second semiconductor block 106B.

In some embodiments, the active element 114A1 is formed on the well region 112 in the first semiconductor block 106A, and the active element 114A2 is formed on another region in the first semiconductor block 106A outside the well region 112. In some embodiments, the active elements 114A1 and 114A2 each includes a gate structure G and a pair of source/drain regions SD. In some embodiments, the gate structure G is formed over the upper surface of the first semiconductor block 106A. The gate structure G includes a gate dielectric layer GD and a gate electrode GE over the gate dielectric layer GD. The source/drain regions SD are formed in the first semiconductor block 106A and on opposite sides of the gate structure G. In an embodiment, the active element 114A1 is a p-type channel field effect transistor (p-channel FET), and the active element 114A2 is an n-channel FET. In some embodiments, the active elements 114A1 and 114A2 will be electrically connected to each other through a subsequently formed interconnect structure to be operated as another active element, such as an inverter.

Similarly, the active element 114B1 formed on the second semiconductor block 106B includes a gate structure G and a pair of source/drain regions SD. In some embodiments, the gate structure G is formed over the upper surface of the second semiconductor block 106B. The gate structure G includes a gate dielectric layer GD and a gate electrode GE over the gate dielectric layer GD. The source/drain regions SD are formed in the second semiconductor block 106B and on opposite sides of the gate structure G.

In illustrated embodiments, the active elements are planar FETs. In some other embodiments, the active elements may be complementary metal oxide semiconductor (CMOS) FETs, FinFETs, bipolar junction transistors (BJTs), thin-film transistors (TFTs), or the like. Furthermore, one or more active elements may be formed in a single semiconductor block and be electrically connected to each other through a subsequently formed interconnect structure to be operated as various active elements, such as logic circuits (e.g., “NOT” gate, “AND” gate, “OR” gate etc.). In addition, the active element described herein include at least a gate structure (or referred as a gate) which is configured to switch the active element. The current flowing through a channel between the source/drain regions may flow or be blocked by applying a voltage to the gate structure.

In some embodiments, the active elements 114A1, 114A2 and 114B1 are formed by forming a dielectric layer and a conductive material layer. The dielectric layer may be made of, or include, silicon oxide (SiO₂), silicon nitride (SiN), a high-k dielectric material, a combination thereof, multilayer thereof, or the like. The dielectric layer may be deposited by chemical vapor deposition (CVD), thermal oxidation, the like, or a combination thereof. The conductive material layer may be made of, or include, doped or undoped polysilicon, Al, Cu, Ti, Ta, W, Co, Mo, TaN, NiSi, CoSi, or the like. The conductive material layer may be deposited by CVD, physical vapor deposition (PVD), thermal growth in furnace, the like, or a combination thereof. Then, a patterning process including photolithography and etching process is performed on the dielectric layer and the conductive material layer to form the gate dielectric layer GD and the gate electrode GE. Next, the pair of source/drain regions SD is formed in the semiconductor layer 106 on opposite sides of the gate structure G by an implantation process. In some embodiments, the conductivity type of the source/drain regions SD of the active element 114A1 may be p-type, and the conductivity type of the respective source/drain regions SD of the active element 114A2 and 114B may be n-type.

Optionally, silicide (not shown) is formed on the gate electrode GE and the source/drain regions SD of each of the active elements 114A1, 114A2 and 114B1 and on the doped regions 113. The silicide is used to reduce the contact resistance of contacts formed subsequently. In some embodiments, the silicide may be made of, or include, WSi, NiSi, TiSi or CoSi and may be formed by a deposition process, an anneal process and a patterning process.

An inter-layer dielectric (ILD) layer 116 is formed over the upper surface of the semiconductor layer 106 to cover the active elements 114A1, 114A2, and 114B1. In some embodiments, the ILD layer 116 may be made of, or include, phosphosilicate glass (PSG), borophosphosilicate glass (BPSG), undoped silicate glass (USG), fluorinated silicate glass (FSG), the like, multilayers thereof, or a combination thereof. The ILD layer 116 may be formed by CVD, such as PECVD.

A plurality of contacts C is formed in or through the ILD layer 116. The plurality of contacts C is a portion of an interconnect structure to electrically connect the underlying active elements and doped regions. In some embodiments shown in FIG. 1A, the plurality of contacts C includes a contact C1 contacting the source/drain region SD of the active element 114A1, a contact C2 contacting the source/drain region SD of the active element 114A2, a contact C3 contacting the doped region 113 in the first semiconductor block 106A, a contact C4 contacting the doped region 113 in the second semiconductor block 106B, and a contact C5 contacting the gate structure G of the active element 114B 1.

FIG. 1A shows merely five contacts C for the purpose of simplicity and clarity. In some other embodiments, more than five contacts may be formed in the ILD layer 116. For example, the contacts may be formed on the gate structure G and another source/drain region SD of the active element 114A1, may be formed on the gate structure G and another source/drain region SD of the active element 114A2, and/or may be formed on the pair of source/drain regions SD of the active element 114B1.

In some embodiments, the contacts C may be made of, or include, a conductive material, such as tungsten (W), nickel (Ni), titanium (Ti), tantalum (Ta), aluminum (Al), copper (Cu), titanium nitride (TiN), tantalum nitride (TaN), the like, multilayers thereof, or a combination thereof. The contact C may be formed by a patterning process (including photolithography and etching processes), a deposition process, and a planarization process. For example, the contacts C may be formed by performing a patterning process on the ILD layer 116 to form openings (not shown) through the ILD layer 116, depositing the conductive material over the ILD layer 116 to fill the openings, and then performing a planarization process such as CMP on the conductive material.

Multiple layered inter-metal dielectric (IMD) layers 120 are formed over the upper surface of the ILD layer 116. In the illustrated embodiments, the multiple layered IMD layers 120 includes a 1^{st} layer of the IMD layers 120-1, an Xth layer of the IMD layers 120-X, and a Yth layer of the IMD layers 120-Y which are sequentially stacked over the upper surface of the ILD layer 116, where X and Y are positive integers greater than one and Y is greater than X. In the illustrated embodiments, the thickness of the Xth layer of the IMD layers 120-X is shown to be thicker than the thickness of the 1^{st} layer of the IMD layers 120-1 and the thickness of the Yth layer of the IMD layers 120-Y to represent that the Xth layer of the IMD layers 120-X may be a single layered structure or a multilayered structure. In addition, although not shown, addition IMD layers may be formed over the Yth layer of the IMD layers 120-Y.

Metal lines L and vias V are formed in each layer of the IMD layers 120. The metal lines L and the vias V are a portion of the interconnect structure. The interconnect structure formed by the combination of the metal lines L, the vias V, and contacts C can provide electrical connection paths between the elements (e.g., the active elements 114A1 and 114A2) on a single region (e.g., the first semiconductor block 106A) and/or between the elements (e.g., the active elements 114A1, 114A2 and the active element 114B1) on different regions (e.g., the first semiconductor block 106A and the second semiconductor block 106B).

In some embodiments, the IMD layers 120 may be made of, or include, silicon oxide, silicon nitride, silicon oxynitride, silicon carbide, silicon carbon-nitride (SiCN), silicon carbon-oxide (SiOC), a low-k dielectric material, PSG, BPSG, USG, spin-on-glass (SOG), hydrogen silsesquioxane (HSQ), the like, multilayers thereof, or a combination thereof. Each layer of the IMD layers 120 may be formed by CVD such PECVD or HDP-CVD, or spin-on coating.

After one layer of the IMD layers 120 is formed, the metal lines L and the vias V are formed in this layer of IML layers 120. For example, a 1^{st} layer of the metal lines L1 and a 1^{st} layer of the vias Vi formed thereon are formed in the 1^{st} layer of the IMD layers 120-1; an Xth layer of the metal lines LX and an Xth layer of the vias VX formed thereon are formed in the Xth layer of the IMD layers 120-X; and a Yth layer of the metal lines LY are formed in the Yth layer of the IMD layers 120-Y. The Xth layer of the metal lines LX and vias VX may also be a single layered structure or a multilayered structure correspondingly disposed in the Xth layer of the IMD layers 120-X. The Xth layer of the metal lines LX and vias VX are denoted by solid lines herein. In addition, For the purpose of simplicity and clarity, FIG. 1A does not show a Yth layer of the vias. In some embodiments, the metal lines L and the vias V may be made of, or include, conductive materials, such as tungsten (W), nickel (Ni), titanium (Ti), tantalum (Ta), aluminum (Al), copper (Cu), titanium nitride (TiN), tantalum nitride (TaN), the like, multilayers thereof, or a combination thereof. The metal lines L and the vias V may be formed by a single damascene process or a dual damascene process, which include etching processes (e.g., a dry etching process) and deposition processes (e.g., sputtering or plating).

After the IMD layers 120 and the interconnect structure including the metal lines L and the vias V are formed, a semiconductor device 100A is produced.

In the embodiments shown in FIG. 1A, the semiconductor device 100A includes the SOI substrate 108. The SOI substrate 108 includes the semiconductor substrate 102, the semiconductor layer 106, and the BOX layer 104 disposed between the semiconductor substrate 102 and the semiconductor layer 106. The semiconductor layer 106 includes the first semiconductor block 106A and the second semiconductor block 106B. The first and second semiconductor layers 106A and 106B are separated from each other by the isolation structure 110.

The semiconductor device 100A also includes the active elements 114A1 and 114A2 disposed on the first semiconductor block 106A and the active element 114B1 disposed on the second semiconductor block 106B. The semiconductor device 100A also includes the interconnect structure disposed over the semiconductor layer 106. The interconnect structure includes the plurality of contacts C, and the multiple layered metal lines L and vias V sequentially arranged over the plurality of contacts C to provide various paths to electrically connect elements on a single region (e.g., the first semiconductor block 106A) and/or different regions (e.g., the first semiconductor block 106A and the second semiconductor block 106B).

The configuration of the interconnect structure of the semiconductor device 100A is described in detail below.

In some embodiments, one source/drain region SD (such as a source region) of the active element 114A1 is electrically connected to one source/drain region SD (such as a drain region) of the active element 114A2 through a path including the contact C1, the 1^{st} layer of the metal lines L1-1, the contact C2. The active element 114A1 and the elements 114A2 may be operated as another active element, such as an inverter.

In some embodiments, the source/drain region SD of the active element 114A1 is electrically connected to the gate structure G of the active element 114B1 through a first path. The first path transmits a signal from the source/drain region SD of the active element 114A1 to the gate structure G of the active element 114B1 to turn on the active element 114B1. The first path includes, in sequence, the contact C1, the 1^{st} layer of the metal lines L1-1, the 1^{st} layer of the vias V1-1, the Xth layer of the metal lines/vias LX/VX-1, the Yth layer of the metal lines LY-1, the Xth layer of the metal lines/vias LX/VX-2, the 1^{st} layer of the vias V1-3, the 1^{st} layer of the metal lines L1-3, and the contact C5. In this embodiment, the first path is formed in the step of forming the Yth layer of the metal lines LY. In other words, the highest layer of the metal lines provided to the first path is the Yth layer of the metal lines LY. Similarly, the source/drain region SD of the active element 114A2 is also electrically connected to the gate structure G of the active element 114B1, and the path connecting the two starts from the contact C2 instead of the contact C1.

In the embodiments shown in FIG. 1A, the first semiconductor block 106A is electrically connected to the second semiconductor block 106B through a second path. In the embodiments of the present disclosure, the second path is a discharge path to balance the induced charge difference between the first semiconductor block 106A and the second semiconductor block 106B. This will be described in detail below. The second path includes, in sequence, the contact C3, the 1^{st} layer of the metal lines L1-2, and the contact C4. In this embodiment, the second path is formed in the step of the 1^{st} layer of the metal lines L1. In other words, the highest layer of the metal lines provided to the second path is the 1^{st} layer of the metal lines L1. In the illustrated embodiments, the 1^{st} layer of the metal lines L1-2 is in contact with the contact C3 and contact C4. The contact C3 and C4 contact the upper surfaces of the first semiconductor block 106A and the second semiconductor block 106B (or the upper surface of the silicide, if any) respectively. In specific, the contact C3 and C4 contact the doped regions 113 in the first semiconductor block 106A and the second semiconductor block 106B respectively. In the embodiments shown FIG. 1A, the doped regions 113 in contact with the contacts C3 and C4 are not a portion of the active elements (such as not a source/drain region).

The etching processes (such as dry etching process) for forming trenches of the metal lines or holes of the vias and/or the deposition process (such as PECVD or HDP-CVD processes) for forming the dielectric layer may be plasma-based processes. It is worth noting that during a plasma-based process, the insulating material of the BOX layer 104 generates induced charges due to high-frequency plasma. The amount of the induced charge in a semiconductor block is positively correlated to the area of the semiconductor block from a top view. For example, the greater of the area of the semiconductor block, the more induced charges there are therein. The amount of the induced charge increases as the plasma-based process continues.

In some embodiments, when viewed from a top view, the first semiconductor block 106A has a first area, and the second semiconductor block 106B has a second area. When the first area is greater than the second area, during a plasma-based process, the amount of the induced charge in the first semiconductor block 106A may be more than the amount of the induced charge in the second semiconductor block 106B. The induced charges in the first semiconductor block 106A may flow to the gate dielectric layer GD of the gate structure G of the active element 114B 1 on the second semiconductor block 106B through the first path, thereby increasing the likelihood of plasma induced damage (PID).

Moreover, the likelihood of PID may be related to the material, thickness, or area of the gate dielectric layer. For example, the gate dielectric layer GD of the gate structure G of the active element 114B1 has a third area, and the likelihood of PID is increased significantly when the first area, the second area, and the third area satisfy the following equation:

((the first area−the second area)/the third area)>200000.

In the embodiments shown in FIG. 1A, the formation of the second path (by forming the 1^{st} layer of the metal lines L1) is earlier than the formation of the first path (by forming the Yth layer of the metal lines LY). Moreover, because the first path ends at the gate dielectric layer GD of the gate structure G and the second path ends at the upper surface of the semiconductor layer 106, the overall resistance of the second path is less than the overall resistance of the first path. Therefore, in the plasma-based processes before, during or after the formation of the first path (or the formation of the Yth layer of the metal lines LY), the induced charge difference between the first semiconductor block 106A and the second semiconductor block 106B can be balanced through the second path after the formation of the second path (or the formation of the 1^{st} layer of the metal lines L1). As a result, the likelihood of PID can be reduced, which increases the process yield of the semiconductor device.

Refer to FIG. 1B, which is a cross-sectional view of a semiconductor device 100B in accordance with some other embodiments of the present disclosure. Elements or layers in FIG. 1B that are the same or similar to those in FIG. 1A are denoted by like reference numerals that have the same meaning, and the description thereof will not be repeated for the sake of brevity. The difference between the embodiments shown in FIG. 1B and FIG. 1A is that the second path connecting the first semiconductor block 106A to the second semiconductor block 106B includes the Xth layer of the metal lines/vias LX/VX.

In the embodiments shown in FIG. 1B, the first semiconductor block 106A is electrically connected to the second semiconductor block 106B through the second path. The second path includes, in sequence, the contact C3, the 1^{st} layer of the metal lines L1-2, the 1^{st} layer of the vias V1-2, the Xth layer of the metal lines/vias LX/VX-3, the 1^{st} layer of the vias V1-4, the 1^{st} layer of the metal lines L1-4, and the contact C4. In this embodiment, the second path is formed in the step of forming the Xth layer of the metal lines LX. In other words, the highest layer of the metal lines provided to the second path is the Xth layer of the metal lines LX.

In the embodiments shown in FIG. 1B, the formation of the second path (by forming the Xth layer of the metal lines LX) is earlier than the formation of the first path (by forming the Yth layer of the metal lines LY). Moreover, the overall resistance of the second path is less than the overall resistance of the first path. Therefore, in the plasma-based processes before, during or after the formation of the first path (or the formation of the Yth layer of the metal lines LY), the induced charge difference between the first semiconductor block 106A and the second semiconductor block 106B can be balanced through the second path after the formation of the second path (or the formation of the Xth layer of the metal lines LX). As a result, the likelihood of PID can be reduced, which increases the process yield of the semiconductor device.

Refer to FIG. 1C, which is a cross-sectional view of a semiconductor device 100C in accordance with some other embodiments of the present disclosure. Elements or layers in FIG. 1C that are the same or similar to those in FIG. 1A are denoted by like reference numerals that have the same meaning, and the description thereof will not be repeated for the sake of brevity. The difference between the embodiments shown in FIG. 1C and FIG. 1A is that the second path connecting the first semiconductor block 106A to the second semiconductor block 106B includes the Yth layer of the metal lines LY.

In the embodiments shown in FIG. 1C, the Yth layer of the metal lines LY-1 and LY-3 are electrically connected behind the cross-sectional view of FIG. 1C, which is indicated by a broken line. The source/drain region SD of the active element 114A1 is electrically connected to the gate structure G of the active element 114B1 through the first path which includes the Yth layer of the metal lines LY-1 and LY-3. In the embodiments shown in FIG. 1C, the first semiconductor block 106A is electrically connected to the second semiconductor block 106B through the second path. The second path includes, in sequence, the contact C3, the 1^{st} layer of the metal lines L1-2, the 1^{st} layer of the vias V1-2, the Xth layer of the metal lines/vias LX/VX-3, the Yth layer of the metal lines LY-2, the Xth layer of the metal lines/vias LX/VX-4, the 1^{st} layer of the vias V1-4, the 1^{st} layer of the metal lines L1-4, and the contact C4. In this embodiment, the second path is formed in the step of forming the Yth layer of the metal lines LY. In other words, the highest layer of the metal lines provided to the second path is the Yth layer of the metal lines LY.

In the embodiments shown in FIG. 1C, the formation of the second path (by forming the Yth layer of the metal lines LY) is at the same layered as the formation of the first path (by forming the Yth layer of the metal lines LY). However, because the overall resistance of the second path is less than the overall resistance of the first path, the second path is still the discharge path for induced charges. Therefore, in the plasma-based processes during or after the formation of the first path and the second path (or the formation of the Yth layer of the metal lines LY), the induced charge difference between the first semiconductor block 106A and the second semiconductor block 106B can be balanced through the second path. As a result, the likelihood of PID can be reduced, which increases the process yield of the semiconductor device.

In the embodiments shown in FIGS. 1A-1C, the portion of the interconnect structure which provides or constitutes the first path is completely different from the portion of the interconnect structure which provides or constitutes the second path. In other words, the first path and the second path do not share any of the contacts C or any of the metal lines/vias L/V.

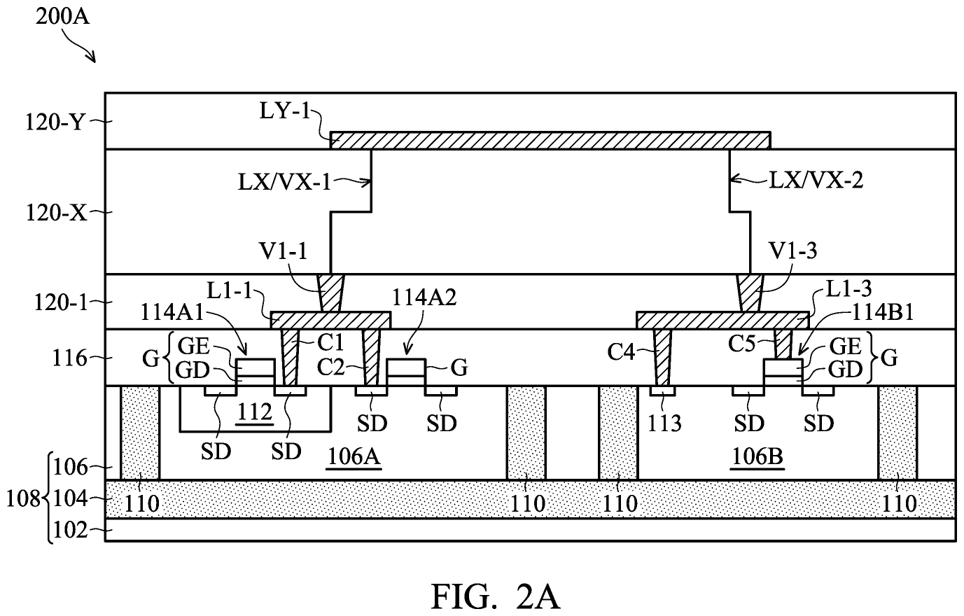

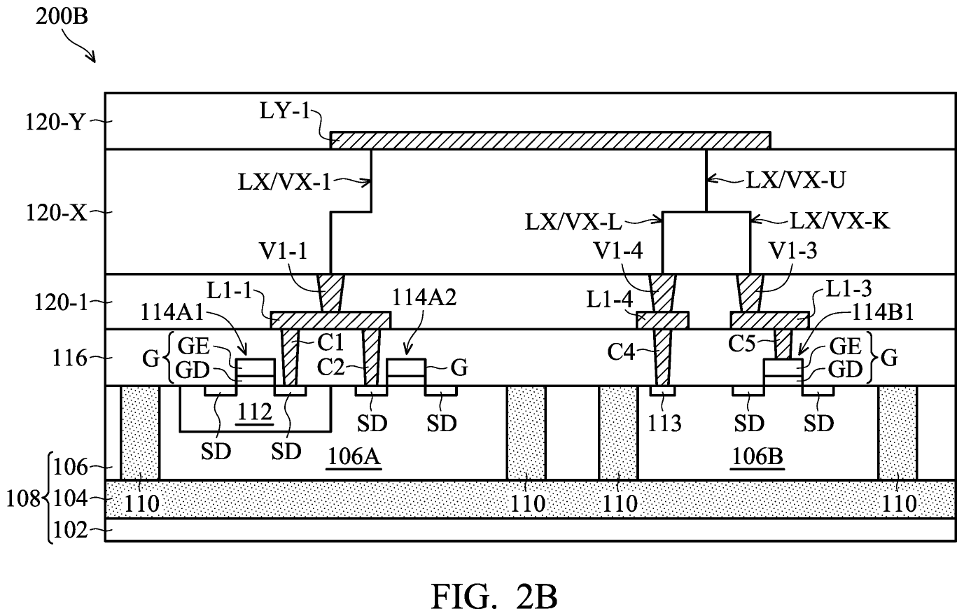

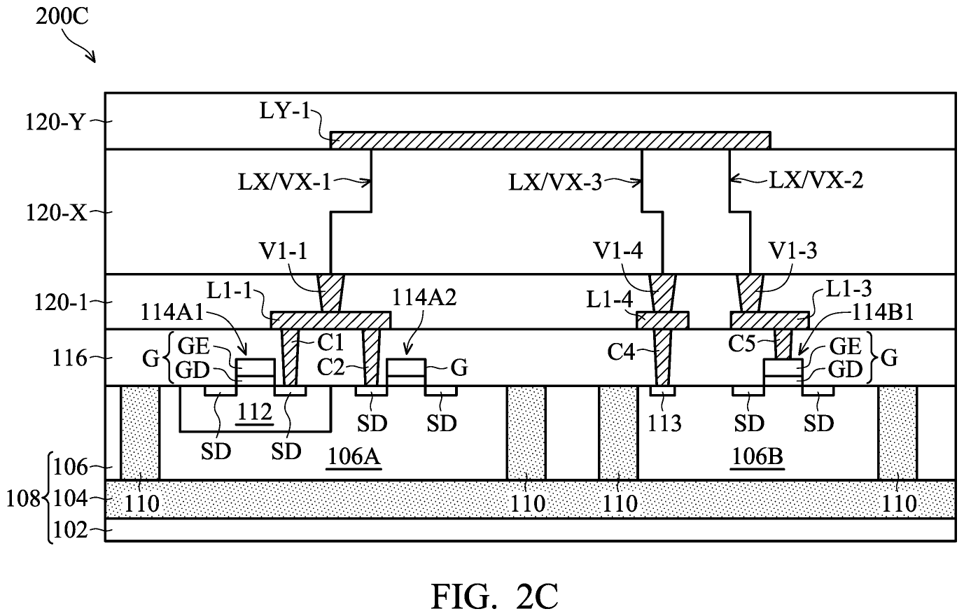

Refer to FIGS. 2A-2C, which are cross-sectional views of semiconductor devices 200A, 200B and 200C in accordance with some other embodiments of the present disclosure. Elements or layers in FIGS. 2A-2C that are the same or similar to those in FIG. 1A are denoted by like reference numerals that have the same meaning, and the description thereof will not be repeated for the sake of brevity. The difference between the embodiments shown FIGS. 2A-2C and the FIG. 1A is that the first path and the second path shown in FIGS. 2A-2C share some of the contacts C and/or some of the metal lines/vias L/V.

In the embodiments shown in FIGS. 2A-2C, the source/drain region SD of the active element 114A1 (or the active element 114A2) is electrically connected to the gate structure G of the active element 114B1 through the first path, as described above with respect to FIG. 1A. Moreover, the first semiconductor block 106A is electrically connected to the second semiconductor block 106B through the second path. In the embodiments shown in FIGS. 2A-2C, the doped region 113 is not formed in the first semiconductor block 106A. The second path starts from the source/drain region SD of the active element 114A1 (or the active element 114A2) and ends at the doped region 113 in the second semiconductor block 106B. In specific, the first path and the second path include the contact C1 which contacts the source/drain region SD of the active element 114A1. As shown in FIGS. 2A-2C, the second path includes a portion of the interconnect structure which is shared with the first path and a portion of the interconnect structure which is not shared with the first path.

For example, in the embodiments shown in FIG. 2A, the portion of the second path which is shared with the first path includes, in sequence, the contact C1 (or C2), the 1^{st} layer of the metal lines L1-1, the 1^{st} layer of the vias V1-1, the Xth layer of the metal lines/vias LX/VX-1, the Yth layer of the metal lines LY-1, the Xth layer of the metal lines/vias LX/VX-2, the 1^{st} layer of the vias V1-3, and the 1^{st} layer of the metal lines L1-3. The portion of the second path which is not shared with the first path includes the contact C4.

For example, in the embodiments shown in FIG. 2B, the portion of the second path which is shared with the first path includes, in sequence, the contact C1 (or C2), the 1^{st} layer of the metal lines L1-1, the 1^{st} layer of the vias V1-1, the Xth layer of the metal lines/vias LX/VX-1, the Yth layer of the metal lines LY-1, an upper portion (or higher layers) of the Xth layer of the metal lines/vias LX/VX-U. The portion of the second path which is not shared with the first path includes, in sequence, a lower portion (lower layers) of the Xth layer of the metal lines/vias LX/VX-L, the 1^{st} layer of the vias V1-4, the 1^{st} layer of the metal lines L1-4, and the contact C4. In a certain embodiment, when the Xth layer of the metal lines is a single layered structure, the first path and the second path share the Xth layer of the metal lines/vias LX/VX.

For example, in the embodiments shown in FIG. 2C, the portion of the second path which is shared with the first path includes, in sequence, the contact C1 (or C2), the 1^{st} layer of the metal lines L1-1, the 1^{st} layer of the vias V1-1, the Xth layer of the metal lines/vias LX/VX-1, and the Yth layer of the metal lines LY-1. The portion of the second path which is not shared with the first path includes, in sequence, the Xth layer of the metal lines/vias LX/VX-3, the 1^{st} layer of the vias V1-4, the 1^{st} layer of the metal lines L1-4, and the contact C4.

In the embodiments shown in FIGS. 2A-2C, the formation of the second path (by forming the Yth layer of the metal lines LY) is at the same layer as the formation of the first path (by forming the Yth layer of the metal lines LY). However, because the overall resistance of the second path is less than the overall resistance of the first path, the second path is still the discharge path for induced charges. Therefore, in the plasma-based processes during or after the formation of the first path and the second path (or the formation of the Yth layer of the metal lines LY), the induced charge difference between the first semiconductor block 106A and the second semiconductor block 106B can be balanced through the second path. As a result, the likelihood of PID can be reduced, which increases the process yield of the semiconductor device.

FIGS. 3A and 3B are top views of semiconductor devices 300A and 300B in accordance with some embodiments of the present disclosure. Elements or layers in FIGS. 3A and 3B that are the same or similar to those in FIG. 1A are denoted by like reference numerals that have the same meaning, and the description thereof will not be repeated for the sake of brevity. The difference between the embodiments shown FIGS. 3A and 3B and the FIG. 1A is that the semiconductor devices 300A and 300B also include a plurality of third semiconductor blocks 106C, and a plurality of active elements 114C1 disposed on the respective third semiconductor blocks 106C.

In the embodiments shown in FIGS. 3A and 3B, the isolation structure 100 is formed in or through the semiconductor layer 106 by the process described above with respect to FIG. 1A. The semiconductor layer 106 is divided into the first semiconductor block 106A, the second semiconductor block 106B, and the plurality of third semiconductor blocks 106C by the isolation structure 110. The one or more active elements are formed on respective semiconductor blocks 106A, 106B and 106C. In some embodiments, the active elements 114C1 on the semiconductor blocks 106C and the method for forming the active elements 114C1 may be the same as or similar to those described above with respect to FIG. 1A. Next, the interconnect structure (not shown in FIGS. 3A and 3B) is formed over the semiconductor layer 106. After the interconnect structure is formed, the semiconductor devices 300A and 300B are produced.

The interconnect structure (not shown in FIGS. 3A and 3B) provides electrical connection paths between the elements in the different regions, and the electrical connection paths are indicated by solid lines.

In some embodiments, the respective source/drain regions SD of the active elements 114C1 on the third semiconductor blocks 106C are electrically connected to the source/drain region SD of the active elements 114A1 on the first semiconductor block 106A through the path P provided by the interconnect structure. In some embodiments, the path P is not connected to the gate structure G of any of the active elements 114C1 and the active element 114A1. Moreover, the source/drain region SD of the active element 114A2 on the first semiconductor block 106A is electrically connected to the gate structure G of the active element 114B1 on the second semiconductor block 106B through a first path P1. The first path P1 may be the first path described above with respect to FIG. 1A. The first path P1 transmits a signal from the source/drain region SD of the active element 114A1 to the gate structure G of the active element 114B1 to turn on the active element 114B1.

Referring to FIG. 3A, the first semiconductor block 106A is electrically connected to the second semiconductor block 106B through a second path P2. The second path P2 may be the second path described above with respect to FIGS. 1A-1C. Referring to FIG. 3B, the first semiconductor block 106A is electrically connected to the second semiconductor block 106B through a second path P2. The second path P2 may be the second path described above with respect to FIGS. 2A-2C. In the embodiments of the present disclosure, the second paths P2 are discharge paths to balance the charge difference between the first semiconductor block 106A, the second semiconductor block 106B, and the third semiconductor blocks 106C.

Although the top views of FIGS. 3A and 3B show that the area of the first semiconductor block 106A is greater than the area of the second semiconductor block 106B and the area of the third semiconductor block 106C, the respective areas of the semiconductor blocks 106A, 106B, and 106C are not limited thereto. For example, the area of the first semiconductor block 106A and the area of the third semiconductor block 106C may be less than the area of the second semiconductor block 106B.

In some embodiments, the first area is the total area of the first semiconductor block 106A and the plurality of third semiconductor blocks 106C when viewed from a top view, and the second semiconductor block 106B has a second area. When the first area is greater than the second area, the total amount of the induced charge in the first semiconductor block 106A and the plurality of the third semiconductor blocks 106C during a plasma-based process may be greater than the amount of the induced charge in the second semiconductor block 106B. The induced charges in the first semiconductor block 106A and the plurality of third semiconductor blocks 106C may flow to the gate dielectric layer GD of the gate structure G of the active element 114B1 on the second semiconductor block 106B through the path P and the first path P1, thereby increasing the likelihood of PID.

In addition, the gate dielectric layer GD of the gate structure G of the active element 114B1 has a third area, and the likelihood of PID is increased significantly when the first area, the second area and the third area satisfy the following equation:

((the first area−the second area)/the third area)>200000.

In the illustrated embodiments, the first semiconductor block 106A is electrically connected to the second semiconductor block 106B by forming the second path P2 so that the induced charge difference between the first semiconductor block 106A, the second semiconductor block 106B, and the third semiconductor blocks 106C can be balanced. As a result, the likelihood of PID can be reduced, which increases the process yield of the semiconductor device.

In summary, in the embodiments of the present disclosure, the induced charges formed in the different semiconductor blocks due to plasma-based processes can be balanced through a discharge path provided by the interconnect structure, thereby reducing the likelihood of PID.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a silicon-on-insulator (SOI) substrate including a semiconductor substrate, a semiconductor layer, and a buried oxide layer disposed between the semiconductor substrate and the semiconductor layer, wherein the semiconductor layer includes a first semiconductor block and a second semiconductor block which are separated from each other by an isolation structure in the semiconductor layer;
a first active element and a second active element disposed on the first semiconductor block and the second semiconductor block respectively; and
an interconnect structure disposed over the semiconductor layer, wherein the interconnect structure includes a plurality of contacts and multiple layered metal lines sequentially arranged over the plurality of contacts to provide a first path and a second path,
wherein a source/drain region of the first active element is electrically connected to a gate structure of the second active element through the first path, and
wherein the first semiconductor block is electrically connected to the second semiconductor block through the second path, wherein the second path includes a first contact that is in contact with an upper surface of the second semiconductor block.

2. The semiconductor device as claimed in claim 1, wherein the second path includes an Xth layer of the metal lines, and the first path includes a Yth layer of the metal lines, and wherein X is less than or equal to Y.

3. The semiconductor device as claimed in claim 1, wherein the first path and the second path do not share any of the contacts or metal lines.

4. The semiconductor device as claimed in claim 1, wherein the second path includes a second contact that is in contact with an upper surface of the first semiconductor block.

5. The semiconductor device as claimed in claim 4, wherein the first contact is in contact with a doped region in the second semiconductor block that is not a source/drain region, and the second contact is in contact with a doped region in the first semiconductor block that is not a source/drain region.

6. The semiconductor device as claimed in claim 4, wherein the second path includes a 1^{st} layer of the metal lines contacting the first contact and the second contact.

7. The semiconductor device as claimed in claim 1, wherein the first path and the second path share the contacts or the metal lines.

8. The semiconductor device as claimed in claim 1, wherein the first path and the second path include a second contact that is in contact with the source/drain region of the first active element.

9. The semiconductor device as claimed in claim 1, wherein when viewed from a top view, the first semiconductor block has a first area and the second semiconductor block has a second area that is smaller than the first area.

10. The semiconductor device as claimed in claim 1, wherein the semiconductor layer further includes a plurality of third semiconductor blocks, and the semiconductor device further comprises:
a plurality of third active elements disposed on the respective third semiconductor blocks,
wherein respective source/drain regions of the third active elements are electrically connected to the source/drain region of the first active element, and
wherein when viewed from a top view, a first area is the total area of the first semiconductor block and the plurality of third semiconductor blocks, and the second semiconductor block has a second area that is smaller than the first area.

11. The semiconductor device as claimed in claim 10, wherein when viewed from a top view, a gate dielectric layer of the gate structure of the second active element has a third area, and the first area, the second area, and the third area satisfy the following equation: (the first area−the second area)/the third area>200000.

12. The method as claimed in claim 1, wherein the isolation structure extends from an upper surface of the semiconductor layer to the buried oxide layer.

13. The method as claimed in claim 1, wherein the first active element is an inverter.

14. A method for fabricating a semiconductor device, comprising
providing a silicon-on-insulator (SOI) substrate, wherein the SOI substrate includes a semiconductor substrate, a semiconductor layer, and a buried oxide layer between the semiconductor substrate and the semiconductor layer;
forming an isolation structure in the semiconductor layer so that the semiconductor layer is divided into a first semiconductor block and a second semiconductor block by the isolation structure;
forming a first active element and a second active element on the first semiconductor block and the second semiconductor block respectively; and
forming an interconnect structure over the semiconductor layer, wherein the interconnect structure includes a plurality of contacts and multiple layered metal lines sequentially arranged over the plurality of contacts to provide a first path and a second path,
wherein a source/drain region of the first active element is electrically connected to a gate structure of the second active element through the first path, and
wherein the first semiconductor block is electrically connected to the second semiconductor block through the second path, wherein the second path includes a first contact that is in contact with an upper surface of the second semiconductor block.

15. The method as claimed in claim 14, wherein the second path includes an Xth layer of the metal lines, and the first path includes a Yth layer of the metal lines, and wherein X is less than or equal to Y.

16. The method as claimed in claim 14, wherein the second path includes a second contact that is in contact with an upper surface of the first semiconductor block.

17. The method as claimed in claim 16, wherein the first contact is in contact with the doped region in the second semiconductor block that is not a source/drain region, and the second contact is in contact with the doped region in the first semiconductor block that is not a source/drain region.

18. The method as claimed in claim 14, wherein the first path and the second path include a second contact that is in contact with the source/drain region of the first active element.

19. The method as claimed in claim 14, wherein when viewed from a top view, the first semiconductor block has a first area and the second semiconductor block has a second area that is smaller than the first area.

20. The method as claimed in claim 14, wherein the semiconductor layer is divided further into a plurality of third semiconductor blocks by the isolation structure, and the method further comprises:
forming a plurality of third active elements disposed on the respective third semiconductor blocks,
wherein respective source/drain regions of the third active elements are electrically connected to the source/drain region of the first active element, and
wherein when viewed from a top view, a first area is the total area of the first semiconductor block and the plurality of third semiconductor blocks, and the second semiconductor block has a second area that is smaller than the first area.
